(19) United States
(12) Patent Application Publication
(10) Pub. No.: US 2025/0317112 A1
(43) Pub. Date: Oct. 9, 2025

(54) CONTROL AND CALIBRATION OF LOAD MODULATED POWER AMPLIFIERS

(71) Applicant: Skyworks Solutions, Inc., Irvine, CA (US)

(72) Inventors: David Steven Ripley, Cedar Rapids, IA (US); Nathan Martin Whitters, Cedar Rapids, IA (US); Philip John Lehtola, Cedar Rapids, IA (US); Timothy M. Faughn, Cedar Rapids, IA (US); Serge Francois Drogi, Flagstaff, AZ (US)

(21) Appl. No.: 19/092,337

(22) Filed: Mar. 27, 2025

Related U.S. Application Data
(60) Provisional application No. 63/574,413, filed on Apr. 4, 2024.
(60) Provisional application No. 63/574,417, filed on Apr. 4, 2024.

(51) Int. Cl. H03F 3/24; H03F 1/02; H03F 1/32; H03F 1/56; H03G 3/30

(52) U.S. Cl. CPC H03F 3/245; H03F 1/0222; H03F 1/3241; H03F 1/56; H03G 3/3042; H03F 2200/102; H03F 2200/105; H03F 2200/451

(57) ABSTRACT

Control and calibration for load modulation power amplifiers are disclosed. In certain embodiments, envelope shaping for a modulated power amplifier incorporates shifting of the envelope shaping table response characteristic with a signal power target (for instance, an average power target). Thus, as a voltage level of a power amplifier supply voltage changes for APT for a given power range, a replicated but shifted envelope shaping table response characteristic can be used for load modulation.

### CROSS-REFERENCE TO RELATED APPLICATIONS

This application claims the benefit of priority under 35 U.S.C. § 119 of U.S. Provisional Patent Application No. 63/574,413, filed Apr. 4, 2024 and titled “CONTROL AND CALIBRATION OF LOAD MODULATED POWER AMPLIFIERS,” and of U.S. Provisional Patent Application No. 63/574,417, filed Apr. 4, 2024 and titled “LOAD MODULATED POWER AMPLIFIERS WITH SMOOTHED ENVELOPE SHAPING,” each of which is herein incorporated by reference in its entirety.

### BACKGROUND

### Field

Embodiments of the invention relate to electronic systems, and in particular, to radio frequency (RF) electronics.

### Description of the Related Technology

Power amplifiers are used in RF communication systems to amplify RF signals for transmission via antennas.

Examples of RF communication systems with one or more power amplifiers include, but are not limited to, mobile phones, tablets, base stations, network access points, customer-premises equipment (CPE), laptops, and wearable electronics. For example, in wireless devices that communicate using a cellular standard, a wireless local area network (WLAN) standard, and/or any other suitable communication standard, a power amplifier can be used for RF signal amplification. RF signals have a frequency in the range from about 30 kHz to 300 GHz, for instance, in the range of about 400 MHz to about 7.125 GHz for Frequency Range 1 (FR1) of the Fifth Generation (5G) communication standard or in the range of about 24.250 GHz to about 71.000 GHz for Frequency Range 2 (FR2) of the 5G communication standard.

### SUMMARY

In certain embodiments, the present disclosure relates to a load modulated power amplifier system. The load modulated power amplifier system includes a power amplifier configured to receive a radio frequency signal at an input and to provide an amplified radio frequency signal at an output, a controllable load impedance coupled to the output of the power amplifier and having an impedance that is modulated by a shaped envelope signal, and an envelope shaping table configured to generate the shaped envelope signal based on a signal power of the radio frequency signal. The envelope shaping table has a smoothed response characteristic that is smoothed relative to a constant gain response characteristic to compensate for phase distortion arising from modulating the impedance.

In various embodiments, the smoothed response characteristic spans a power range, the smoothed response characteristic being smoothed over a lower end of the power range. According to a number of embodiments, the smoothed response characteristic is also smoothed over an upper end of the power range relative to the constant gain response characteristic.

In several embodiments, the smoothed response characteristic achieves less than −120 dBm of phase distortion and less than −130 dBm of amplitude distortion.

In some embodiments, the load modulated power amplifier system further includes a power management circuit configured to control a voltage level of the power amplifier supply voltage based on a power target signal. According to a number of embodiments, the load modulated power amplifier system further includes a supply voltage shaping table configured to generate a shaped power supply reference signal for the power management circuit based on the power target signal. In accordance with several embodiments, the load modulated power amplifier system further includes a gain shaping table configured to generate a shaped gain control signal for scaling the radio frequency signal based on the power target signal. According to various embodiments, the load modulated power amplifier system further includes a modulator configured to generate the radio frequency signal based on digital signal data, the modulator receiving the shaped gain control signal. In accordance with a number of embodiment, the shaped envelope table receives the digital signal data to determine the signal power.

In several embodiments, the load modulated power amplifier system further includes a modulator configured to generate the radio frequency signal based on digital signal data. According to a number of embodiments, the shaped envelope table receives the digital signal data to determine the signal power.

In certain embodiments, the present disclosure relates to a mobile device. The mobile device includes a front end system including a power amplifier configured to receive a radio frequency signal at an input and to provide an amplified radio frequency signal at an output, and a controllable load impedance coupled to the output of the power amplifier and having an impedance that is modulated by a shaped envelope signal. The mobile device further includes a transceiver configured to generate the radio frequency signal, the transceiver including an envelope shaping table configured to generate the shaped envelope signal based on a signal power of the radio frequency signal. The envelope shaping table has a smoothed response characteristic that is smoothed relative to a constant gain response characteristic to compensate for phase distortion arising from modulating the impedance.

In several embodiments, the smoothed response characteristic spans a power range, the smoothed response characteristic being smoothed over a lower end of the power range. According to various embodiments, the smoothed response characteristic is also smoothed over an upper end of the power range relative to the constant gain response characteristic.

In some embodiments, the smoothed response characteristic achieves less than −120 dBm of phase distortion and less than −130 dBm of amplitude distortion.

In several embodiments, the mobile device further includes a power management circuit configured to control a voltage level of the power amplifier supply voltage based on a power target signal. According to a number of embodiments, the transceiver further includes a supply voltage shaping table configured to generate a shaped power supply reference signal for the power management circuit based on the power target signal. In accordance with some embodiments, the transceiver further includes a gain shaping table configured to generate a shaped gain control signal for scaling the radio frequency signal based on the power target signal. According to various embodiments, the transceiver further includes a modulator configured to generate the radio frequency signal based on digital signal data, the modulator receiving the shaped gain control signal. In accordance with a number of embodiments, the shaped envelope table receives the digital signal data to determine the signal power.

In some embodiments, the transceiver further includes a modulator configured to generate the radio frequency signal based on digital signal data. According to several embodiments, the shaped envelope table receives the digital signal data to determine the signal power.

In certain embodiments, the present disclosure relates to a method of power amplification in a mobile device. The method includes receiving a radio frequency signal at an input to a power amplifier and providing an amplified radio frequency signal at an output of the power amplifier, modulating an impedance of a controllable load impedance coupled to the output of the power amplifier using a shaped envelope signal, and generating the shaped envelope signal based on a signal power of the radio frequency signal using an envelope shaping table. The envelope shaping table has a smoothed response characteristic that is smoothed relative to a constant gain response characteristic to compensate for phase distortion arising from modulating the impedance.

In some embodiments, the smoothed response characteristic spans a power range, the smoothed response characteristic being smoothed over a lower end of the power range. According to several embodiments, the smoothed response characteristic is also smoothed over an upper end of the power range relative to the constant gain response characteristic.

In various embodiments, the smoothed response characteristic achieves less than −120 dBm of phase distortion and less than −130 dBm of amplitude distortion.

In several embodiments, the method further includes controlling a voltage level of the power amplifier supply voltage based on a power target signal using a power management circuit. According to some embodiments, the method further includes generating a shaped power supply reference signal for the power management circuit based on the power target signal using a supply voltage shaping table. In accordance with a number of embodiments, the method further includes generating a shaped gain control signal for scaling the radio frequency signal based on the power target signal using a gain shaping table. According to various embodiments, the method further includes generating the radio frequency signal based on digital signal data using a modulator that receives the shaped gain control signal. In accordance with several embodiments, the shaped envelope table receives the digital signal data to determine the signal power.

In various embodiments, the method further includes generating the radio frequency signal based on digital signal data using a modulator. According to a number of embodiments, the shaped envelope table receives the digital signal data to determine the signal power.

In certain embodiments, a load modulated power amplifier system is disclosed. The load modulated power amplifier includes a power amplifier configured to receive a radio frequency signal at an input and to provide an amplified radio frequency signal at an output, the power amplifier powered by a power amplifier supply voltage. The load modulated power amplifier further includes a controllable load impedance coupled to the output of the power amplifier and having an impedance controlled by a shaped envelope signal, a power management circuit configured to control a voltage level of the power amplifier supply voltage based on a power target signal, and an envelope shaping table configured to generate the shaped envelope signal based on a signal power of the radio frequency signal. The envelope shaping table proves a first response characteristic for a first power range and a second response characteristic for a second power range, the second response characteristic corresponding to a shifted copy of the first response characteristic.

In some embodiments, the power management circuit sets the power amplifier supply voltage to a first voltage level for the first power range and to a second voltage level for the second power range.

In several embodiments, the power management circuit provides average power tracking based on the power target signal.

In various embodiments, the load modulated power amplifier system further includes a supply voltage shaping table configured to generate a shaped power supply reference signal for the power management circuit based on the power target signal. According to a number of embodiments, the load modulated power amplifier system further includes a gain shaping table configured to generate a shaped gain control signal for scaling the radio frequency signal based on the power target signal. In accordance with several embodiments, the load modulated power amplifier system further includes a modulator configured to generate the radio frequency signal based on digital signal data, the modulator receiving the shaped gain control signal. According to several embodiments, the shaped envelope table receives the digital signal data to determine the signal power. In accordance with a number of embodiments, the supply voltage shaping table and the gain shaping table are calibrated by a four-point calibration. According to several embodiments, the four-point calibration includes a first calibration point of a gain of the power amplifier for a high setting of the power amplifier supply voltage and a low setting of the shaped envelope signal, a second calibration point for the gain for a low setting of the power amplifier supply voltage and the low setting of the shaped envelope signal, a third calibration point for an output power of the power amplifier for the high setting of the power amplifier supply voltage and the high setting of the shaped envelope signal, and a fourth calibration point for the output power for the low setting of the power amplifier supply voltage and the high setting of the shaped envelope signal.

In some embodiments, the envelope shaping table provides a third response characteristic for a third power range, the third response characteristic corresponding to a shifted copy of the second response characteristic.

In various embodiments, the load modulated power amplifier system further includes a modulator configured to generate the radio frequency signal based on digital signal data. According to a number of embodiments, the modulator provides digital pre-distortion to the radio frequency signal, the modulator having a first digital pre-distortion model for the first power range and a second digital pre-distortion model for the second power range, the second digital pre-distortion model corresponding to a shifted copy of the first digital pre-distortion model. In accordance with several embodiments, the shaped envelope table receives the digital signal data to determine the signal power.

In certain embodiments, a mobile device is disclose. The mobile device includes a front end system including a power amplifier configured to receive a radio frequency signal at an input and to provide an amplified radio frequency signal at an output, and a controllable load impedance coupled to the output of the power amplifier and having an impedance controlled by a shaped envelope signal. The mobile device further includes a power management circuit configured to control a voltage level of a power amplifier supply voltage of the power amplifier based on a power target signal, and a transceiver configured to generate the radio frequency signal. The transceiver includes an envelope shaping table configured to generate the shaped envelope signal based on a signal power of the radio frequency signal, the envelope shaping table providing a first response characteristic for a first power range and a second response characteristic for a second power range, the second response characteristic corresponding to a shifted copy of the first response characteristic.

In some embodiments, the power management circuit sets the power amplifier supply voltage to a first voltage level for the first power range and to a second voltage level for the second power range.

In various embodiments, the power management circuit provides average power tracking based on the power target signal.

In some embodiments, the transceiver further includes a supply voltage shaping table configured to generate a shaped power supply reference signal for the power management circuit based on the power target signal. According to several embodiments, the transceiver further includes a gain shaping table configured to generate a shaped gain control signal for scaling the radio frequency signal based on the power target signal. In accordance with a number of embodiments, the transceiver further includes a modulator configured to generate the radio frequency signal based on digital signal data, the modulator receiving the shaped gain control signal. According to various embodiments, the shaped envelope table receives the digital signal data to determine the signal power. In accordance with several embodiments, the supply voltage shaping table and the gain shaping table are calibrated by a four-point calibration. According to a number of embodiments, the four-point calibration includes a first calibration point of a gain of the power amplifier for a high setting of the power amplifier supply voltage and a low setting of the shaped envelope signal, a second calibration point for the gain for a low setting of the power amplifier supply voltage and the low setting of the shaped envelope signal, a third calibration point for an output power of the power amplifier for the high setting of the power amplifier supply voltage and the high setting of the shaped envelope signal, and a fourth calibration point for the output power for the low setting of the power amplifier supply voltage and the high setting of the shaped envelope signal.

In various embodiments, the envelope shaping table provides a third response characteristic for a third power range, the third response characteristic corresponding to a shifted copy of the second response characteristic.

In several embodiments, the transceiver further includes a modulator configured to generate the radio frequency signal based on digital signal data. According to some embodiments, the modulator provides digital pre-distortion to the radio frequency signal, the modulator having a first digital pre-distortion model for the first power range and a second digital pre-distortion model for the second power range, the second digital pre-distortion model corresponding to a shifted copy of the first digital pre-distortion model. In accordance with a number of embodiments, the shaped envelope table receives the digital signal data to determine the signal power.

In certain embodiments, a method of power amplification in a mobile device is disclosed. The method includes receiving a radio frequency signal at an input to a power amplifier and providing an amplified radio frequency signal at an output of the power amplifier. The method further includes controlling a voltage level of a power amplifier supply voltage of the power amplifier based on a power target signal using a power management circuit, controlling an impedance of a controllable load impedance coupled to the output of the power amplifier using a shaped envelope signal, and generating the shaped envelope signal based on a signal power of the radio frequency signal using an envelope shaping table that provides a first response characteristic for a first power range and a second response characteristic for a second power range. The second response characteristic corresponds to a shifted copy of the first response characteristic.

In some embodiments, the method further includes setting the power amplifier supply voltage to a first voltage level for the first power range and to a second voltage level for the second power range using the power management circuit.

In several embodiments, the method further includes providing average power tracking based on the power target signal using the power management circuit.

In various embodiments, the method further includes generating a shaped power supply reference signal for the power management circuit based on the power target signal using a supply voltage shaping table. According to a number of embodiments, the method further includes generating a shaped gain control signal for scaling the radio frequency signal based on the power target signal using a gain shaping table. In accordance with several embodiments, the method further includes generating the radio frequency signal based on digital signal data using a modulator that receives the shaped gain control signal. According to some embodiments, the shaped envelope table receives the digital signal data to determine the signal power. In accordance with a number of embodiments, the method further includes calibrating the supply voltage shaping table and the gain shaping table using a four-point calibration. According to several embodiments, the four-point calibration includes a first calibration point of a gain of the power amplifier for a high setting of the power amplifier supply voltage and a low setting of the shaped envelope signal, a second calibration point for the gain for a low setting of the power amplifier supply voltage and the low setting of the shaped envelope signal, a third calibration point for an output power of the power amplifier for the high setting of the power amplifier supply voltage and the high setting of the shaped envelope signal, and a fourth calibration point for the output power for the low setting of the power amplifier supply voltage and the high setting of the shaped envelope signal.

In some embodiments, the envelope shaping table provides a third response characteristic for a third power range, the third response characteristic corresponding to a shifted copy of the second response characteristic.

In various embodiments, the method further includes generating the radio frequency signal based on digital signal data using a modulator. According to several embodiments, the method further includes using the modulator to provide digital pre-distortion to the radio frequency signal, the modulator having a first digital pre-distortion model for the first power range and a second digital pre-distortion model for the second power range, the second digital pre-distortion model corresponding to a shifted copy of the first digital pre-distortion model. In accordance with some embodiments, the shaped envelope table receives the digital signal data to determine the signal power.

### BRIEF DESCRIPTION OF THE DRAWINGS

Embodiments of this disclosure will now be described, by way of non-limiting example, with reference to the accompanying drawings.

FIG. 1 is a schematic diagram of one embodiment of a load modulated power amplifier.

FIG. 2 is a schematic diagram of another embodiment of a load modulated power amplifier.

FIG. 3 is a schematic diagram of one embodiment of a load modulated power amplifier system.

FIG. 4A is a schematic diagram of another embodiment of a load modulated power amplifier system.

FIG. 4B is a schematic diagram of another embodiment of a load modulated power amplifier system.

FIG. 5A is a schematic diagram of a load modulated power amplifier with calibration according to one embodiment.

FIG. 5B is one example of envelope shaping table response versus signal power target for a load modulated power amplifier.

FIG. 5C is one example of a Smith chart of collector impedance versus control voltage for a load modulated power amplifier.

FIG. 5D is one example of signal, power supply, and load characteristics versus time for a load modulated power amplifier.

FIG. 5E is one example of a graph of gain versus output power for a load modulated power amplifier.

FIG. 5F is one example of a graph of power added efficiency (PAE) versus output power for a load modulated power amplifier.

FIG. 6A is one example of a graph of a 4-point power supply voltage scaling algorithm according to one embodiment.

FIG. 6B is one example of power amplifier supply voltage versus saturated output power after a 2-point calibration for target power and waveform crest factor.

FIG. 7A is one example of a graph of envelope shaping table response versus power range for a load modulated power amplifier.

FIG. 7B is another example of a graph of envelope shaping table response versus power range for a load modulated power amplifier.

FIG. 7C is one example of a graph of amplitude distortion versus relative output power for a load modulated power amplifier.

FIG. 7D is one example of a graph of amplitude distortion versus absolute output power for a load modulated power amplifier.

FIG. 7E is one example of a graph of phase distortion versus relative output power for a load modulated power amplifier.

FIG. 7F is one example of a graph of phase distortion versus absolute output power for a load modulated power amplifier.

FIG. 8A is one example of a graph of gain versus power level using digital pre-distortion (DPD) scaling for a load modulated power amplifier.

FIG. 8B is one example of a graph of phase versus power level using DPD scaling for a load modulated power amplifier.

FIG. 9A is one example of a graph of phase versus output power for a load modulated power amplifier.

FIG. 9B is one example of a graph of shaped envelope voltage versus input power with and without smoothing for a load modulated power amplifier.

FIG. 10 is one example of a graph of output spectrum versus frequency offset for a load modulated power amplifier.

FIG. 11 is a schematic diagram of one embodiment of a mobile device.

FIG. 12A is a schematic diagram of one embodiment of a packaged module.

FIG. 12B is a schematic diagram of a cross-section of the packaged module of FIG. 12A taken along the lines 12B-12B.

### DETAILED DESCRIPTION OF CERTAIN EMBODIMENTS

The following detailed description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

### Example Embodiments of Load Modulated Power Amplifiers

A load modulated power amplifier can include a power amplifier that amplifies a radio frequency (RF) input signal and a load impedance coupled to an output of the power amplifier and that is modulated based on an envelope of the RF input signal. Providing load impedance modulation in this manner provides high efficiency over a wide dynamic range.

In certain implementations, the load impedance includes an output balun including a first winding and a second winding that are electromagnetically coupled to one another. Additionally, the output of the power amplifier is coupled to a first terminal of the first winding (or in a push-pull configuration with a pair of outputs coupled to first and second terminals of the first winding), while an amplified RF signal is outputted from a first terminal of the second winding. The load impedance further includes a controllable capacitor coupled to a second terminal of the second winding (for instance, electrically connected between the second terminal and ground) and having a capacitance controlled by the envelope of the RF signal.

Thus, load modulation can be performed by sweeping an impedance of a termination capacitor on the secondary port of the balun.

In comparison to power amplifiers in which an envelope tracker controls a supply voltage of the power amplifier to track an envelope signal, load modulated power amplifiers have a load impedance controlled based on the envelope signal. Providing load modulation in this manner provides higher efficiency power amplifiers that are less complex than envelope tracking amplifiers, while leveraging circuitry for generating and calibrating the envelope signal for desired performance.

For example, a load modulated power amplifier can be powered by a high efficiency DC-to-DC converter, for instance, a power management unit (PMU) operating with an efficiency of 93% or higher. Such a PMU can, for instance, operate using average power tracking (APT) over 5.5V+2.5-3.0V (power amplifier efficiency can be better at higher supply voltage due to non-zero knee voltage). In contrast, an envelope tracking system may have only 80% efficiency, with the supply voltage ˜2.5-3.0V (power amplifier efficiency can be worse at lower supply voltage due to non-zero knee voltage). A PMU is also referred to herein as a power management circuit or a power management integrated circuit (PMIC).

Load modulated power amplifiers can be included in a wide variety of RF communication systems, including, but not limited to, base stations, network access points, mobile phones, tablets, customer-premises equipment (CPE), laptops, computers, wearable electronics, and/or other communication devices.

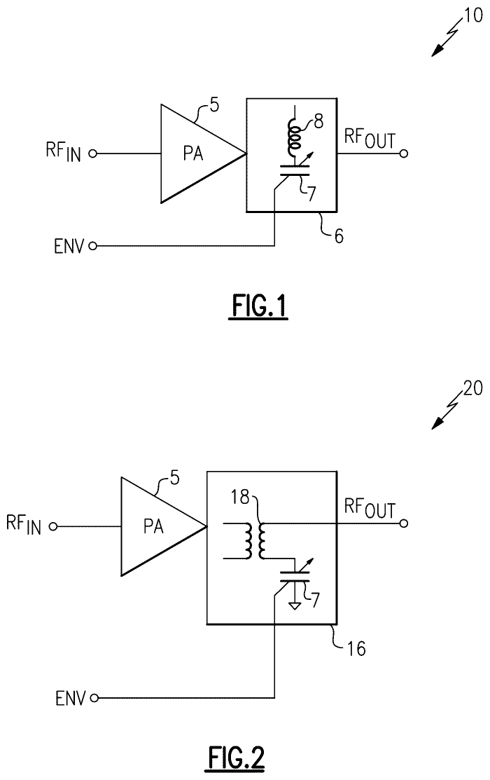

FIG. 1 is a schematic diagram of one embodiment of a load modulated power amplifier 10. The load modulated power amplifier 10 includes a power amplifier 5 and a controllable load impedance 6. The load modulated power amplifier 10 amplifies an RF input signal RF_{IN} to generate an RF output signal RF_{OUT}.

The load modulated power amplifier 10 receives an envelope signal ENV that changes in relation to an envelope of the RF input signal RF_{IN}. The envelope signal ENV is used to control an impedance of the controllable load impedance 6. For example, in this embodiment, the controllable load impedance 6 includes a series combination of an inductor 8 and a controllable capacitor 7, and the envelope signal ENV is used to control a capacitance of the controllable capacitor 7. Although one example of a controllable load impedance is depicted, the teachings herein are applicable to other implementations of controllable load impedances.

FIG. 2 is a schematic diagram of another embodiment of a load modulated power amplifier 20. The load modulated power amplifier 20 of FIG. 2 is similar to the load modulated power amplifier 10 of FIG. 1, except that the load modulated power amplifier 20 of FIG. 2 includes a different implementation of a controllable load impedance 16.

In particular, the controllable load impedance 16 includes a balun 18 and a controllable capacitor 7. An output of the power amplifier 5 drives a first winding of the balun 18. Additionally, a first terminal of a second winding of the balun 18 outputs the RF output signal RF_{OUT}, while a second terminal of the second winding is coupled to the controllable capacitor 7. The controllable capacitor 7 is controlled by the envelope signal ENV.

Changing a value of the controllable capacitor 7 effectively resonates out some of the inductance of the second winding, thereby effectively changing a turn ratio of the balun 18.

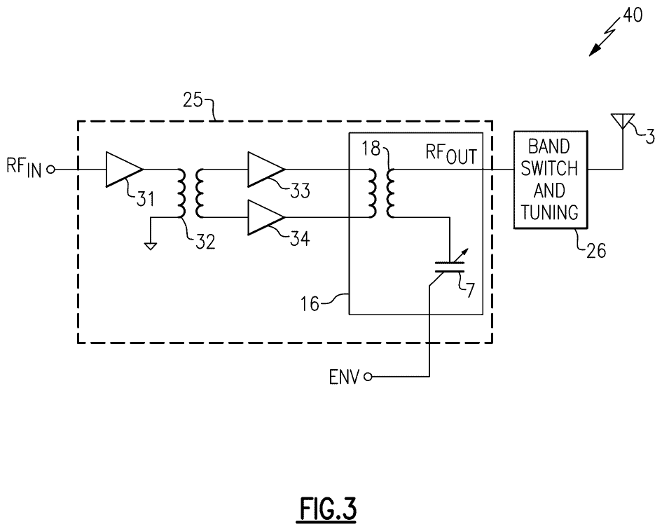

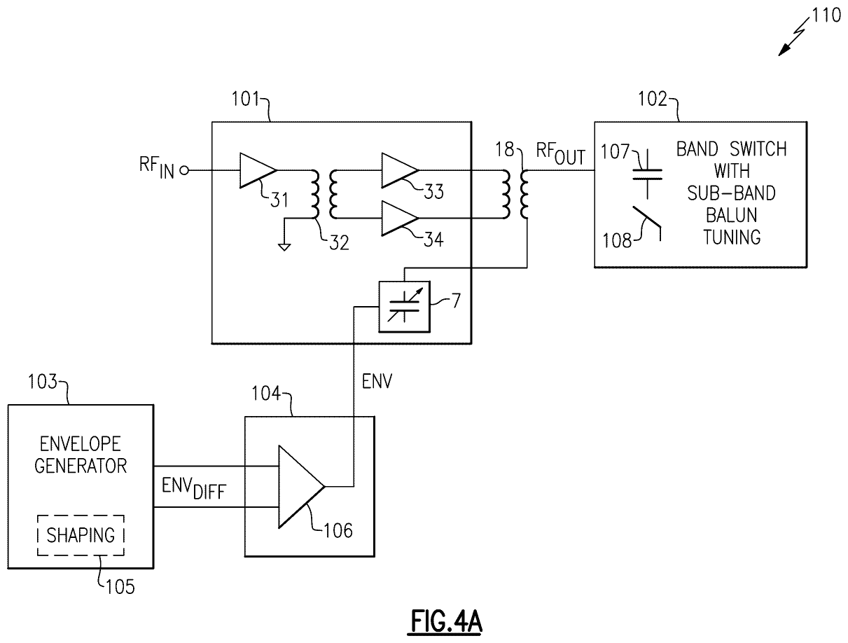

FIG. 3 is a schematic diagram of one embodiment of a load modulated power amplifier system 40. The load modulated power amplifier system 40 includes a load modulated power amplifier 25, a band switching and tuning circuit 26, and an antenna 3.

In the illustrated embodiment, the load modulated power amplifier 25 includes a driver amplifier 31, an input balun 32, a first output amplifier 33, a second output amplifier 34, and a controllable load impedance 16 that includes an output balun 18 and a controllable capacitor 7.

The load modulated power amplifier 25 is implemented as a push-pull amplifier, in this embodiment. Additionally, an output of the first output amplifier 33 is connected to a first terminal of a first winding of the balun 18, while an output of the second output amplifier 34 is connected to a second terminal of the first winding of the balun 18.

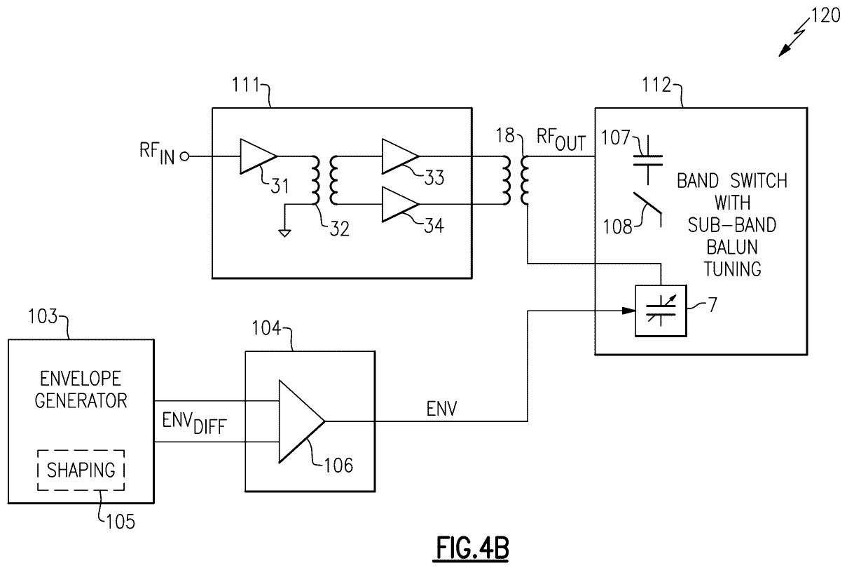

FIG. 4A is a schematic diagram of another embodiment of a load modulated power amplifier system 110. The load modulated power amplifier system 110 includes an output balun 18, a power amplifier die 101, a switch die 102, an envelope generator die 103, and a driver die 104. The power amplifier die 101 includes a driver amplifier 31, an input balun 32, a first output amplifier 33, a second output amplifier 34, and a controllable capacitor 7. The switch die 102 includes a capacitor 107 and a switch 108. Furthermore, the envelope generator die 103 includes a shaping circuit 105 for shaping a differential envelope signal ENV_{DIFF} provided to the driver die 104. The driver die 104 includes an amplifier 106 for receiving the differential envelope signal ENV_{DIFF}, and that outputs an envelope control signal ENV for controlling the controllable capacitor 7.

The load modulated power amplifier system 110 can operate with system level calibration for aligning and shaping the envelope control signal for the controllable capacitor 7 to the RF input signal amplified by the push-pull amplifier. The envelope calibration can be implemented in accordance with any of the embodiments herein.

FIG. 4B is a schematic diagram of another embodiment of a load modulated power amplifier system 120. The load modulated power amplifier system 120 includes an output balun 18, a power amplifier die 111, a switch die 112, an envelope generator die 103, and a driver die 104.

The load modulated power amplifier system 120 of FIG. 4B is similar to the load modulated power amplifier system 110 of FIG. 4A, except that the load modulated power amplifier system 120 illustrates an implementation in which the controllable capacitor 7 is on the switch die 112. Since the switch die 112 is typically implemented using a silicon on insulator (SOI) process and the power amplifier die 111 using a compound semiconductor process (for instance, GaAs), placing the controllable capacitor 7 on the switch die 112 aids in providing a high quality-factor (Q-factor) capacitor.

### Example Embodiments for Control and Calibration of Load Modulated Power Amplifiers

As discussed above, load modulated power amplifiers provide the ability to modulate the power amplifier load and eliminate complex envelope tracking power supply content. Using this technology, the system can use signal envelope information to dynamically modulate the amplifier load to provide improved efficiency. Load modulation provides advantages over envelope tracking due to reduced power supply complexity and/or wider bandwidth operation.

For load modulated power amplifiers to operate efficiently, control and calibration techniques are needed to properly modulate the amplifier load synchronous with the RF signal's envelope.

A number of challenges to load modulation arise as the system provides calibration over a wide range of average output powers.

Moreover, controlling and calibrating a load modulated power amplifier can be further complicated when average power tracking (APT) is used to change the voltage level of the supply voltage of the load modulated power amplifier. For example, when using APT, the supply voltage level of the load modulated power amplifier can change each radio transmit time slot, and the supply voltage level has an impact on the desired calibrated values for other components in the system.

In certain embodiments herein, control and calibration for load modulation incorporates shifting of the envelope shaping table response characteristic with a signal power target (for instance, an average power target). Thus, as a voltage level of a power amplifier supply voltage changes for APT for a given power range, a replicated but shifted envelope shaping table response characteristic can be used for load modulation.

By implementing the load modulated power amplifier in this manner, simplified calibration and control can be achieved with little to no impact on performance. For example, the total amount of calibration data and/or complexity can be reduced relative to an implementation in which an envelope shaping table is separately calibrated for each voltage level of the power amplifier supply voltage and/or for each signal power target level.

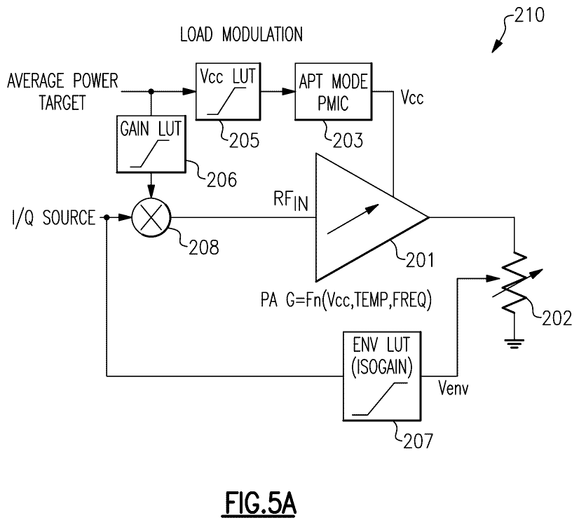

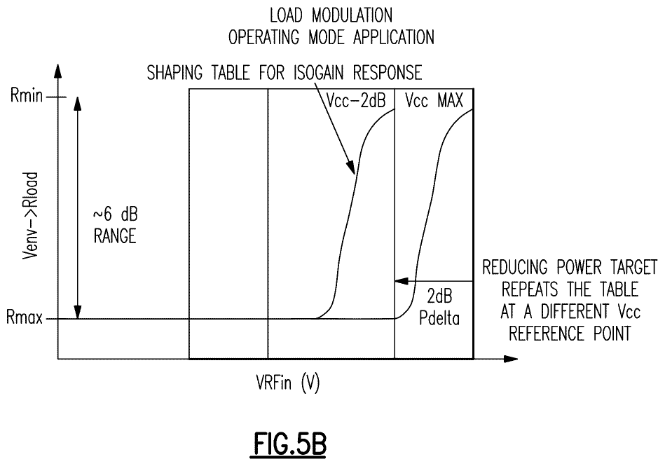

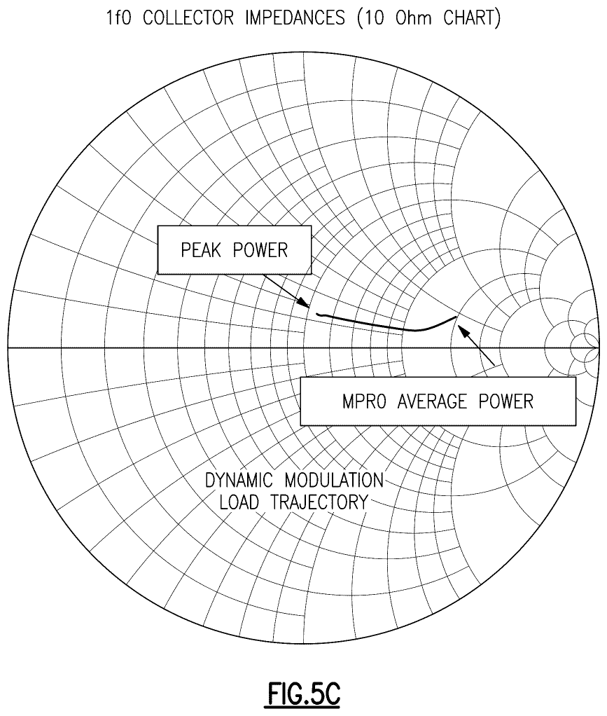

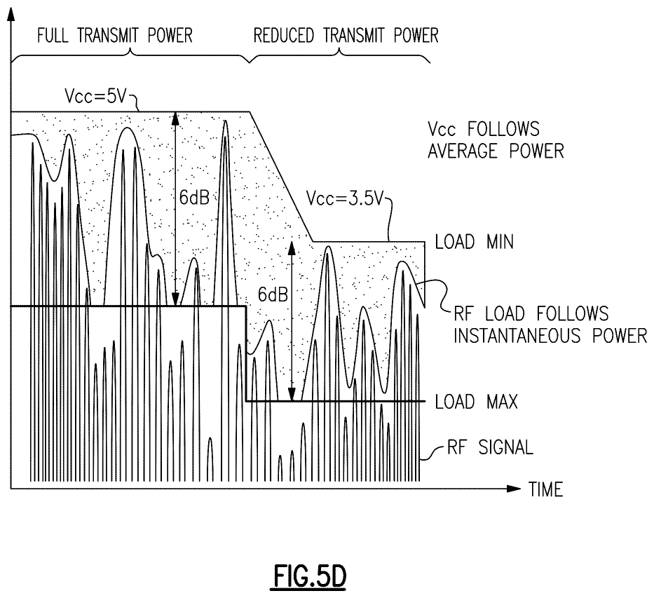

FIG. 5A is a schematic diagram of a load modulated power amplifier with calibration 210 according to one embodiment. The load modulated power amplifier with calibration 210 includes a power amplifier 201, a controllable load 202, a PMIC 203 operating with APT, a power amplifier supply voltage (Vcc) shaping table 205, a gain shaping table 206, an envelope shaping table 207, and a signal modulator 208. The tables 205-207 can also be referred to herein as lookup tables (LUTs).

The PMIC 203 controls a voltage level of the Vcc of the power amplifier 201 based on a value of a shaped power supply reference signal. The shaped power supply reference signal is generated by the Vcc shaping table 205, which maps a power target signal (for instance, an indication of an average power target) to the shaped power supply reference signal. For example, the Vcc shaping table 205 can output a particular value of the shaped supply reference signal for a given value of the power target signal. In some implementations, the power target signal also includes an indication of a peak-to-average power ratio (PAPR) or crest factor of the signal.

In certain implementations, the Vcc shaping table 205 is calibrated using static calibration (for example, a 2-point calibration) to achieve desired Vcc levels or values for APT based on the power target signal. In one example, for each average power target value, the Vcc shaping table 205 is calibrated to provide a corresponding Vcc level for APT.

With continuing reference to FIG. 5A, the gain shaping table 206 maps the power target signal to a shaped gain control signal for the signal modulator 208. For example, the gain shaping table 205 can output a particular value of the shaped gain control signal for a given value of the power target signal.

In certain implementations, the gain shaping table 206 is calibrated using static calibration (for example, a 2-point calibration) to achieve a desired signal amplitude based on the power target signal. In one example, for each average power target value, the gain shaping table 206 is calibrated to provide a corresponding gain value for the signal modulator 208.

As shown in FIG. 5A, the signal modulator 208 receives in-phase (I) and quadrature-phase (Q) signal data from a source (for instance, a baseband processor). The I/Q signal data is used by the signal modulator 208 to generate an RF input signal RF_{IN} for amplification by the power amplifier 201. The signal modulator 208 uses the shaped gain control signal from the gain shaping table 206 to scale the amplitude of the RF input signal RF_{IN}.

In the illustrated embodiment, the envelope shaping table 207 maps I/Q signal data to a shaped envelope signal (Venv). For example, the I/Q signal data provides an indication of the input signal envelope (for instance, by way of a coordinate rotation computation or other suitable method for detecting instantaneous signal power and/or envelope) and thus can be used by the envelope shaping table 207 to provide a corresponding shaped envelope signal level for each input signal power.

The envelope shaping table 207 is also calibrated to be a function of the Vcc voltage level for APT. In certain embodiments, the envelope shaping table 207 includes replicated or copied shaping data that is used for each Vcc but is shifted in each power range. Thus, reducing the power target repeats the shaping table at a different Vcc reference point.

In some implementations, a calibrated delay element is included in the signal path (for instance, in the modulator 208) or in the envelope path (for instance, at the control input of the controllable load 202) to aid in aligning the shaped envelope signal (Venv) against the RF input signal RF_{IN}. Such a delay element can be calibrated by a table that controls the delay element's delay based on input signal power.

The power amplifier 201 can also have a gain that is calibrated (for instance, by controlling a bias to the power amplifier 201). The gain can be a function of temperature, signal frequency, power supply voltage level, and/or other parameters.

In certain implementations, the signal modulator 208 is implemented to provide digital pre-distortion (DPD) to the RF input signal RF_{IN} to compensate for non-linearities of the power amplifier 201. The DPD also serves to correct for the remaining amplitude distortion (AM/AM) and phase distortion (AM/PM) terms remaining after calibration of the tables 205-207.

To reduce complexity, a shared DPD model can be used that shifts with the power target signal. For example, a replicated or copied DPD model can be used that is shifted for each power range.

FIG. 5B is one example of envelope shaping table response versus signal power target for a load modulated power amplifier. The example depicts one embodiment of a calibration scheme for a load modulated power amplifier, such as for the envelope shaping table 207 of FIG. 5A.

As the signal power target (indicated by a voltage VRFin, in this example) changes, the power amplifier supply voltage (Vcc) for APT also changes for different power ranges. For example, for a high signal power target, Vcc can have a maximum voltage level (Vcc MAX), while for a 2 dB lower signal power target Vcc can be reduced (for instance, to Vcc−2 dB). Although two example Vcc values for APT are shown, the load modulated power amplifier system can operate with additional Vcc levels for APT associated with other power ranges.

In the illustrated embodiment, shaping data for providing mapping between input power and a shaped envelope voltage (Venv) for controlling a load impedance (Rload) of a load modulated power amplifier is shown. The shaping data is a function of the Vcc level (and associated power range) chosen for APT.

To reduce calibration complexity, in the illustrated embodiment the same shaping data is used for each Vcc but is shifted in each power range. Thus, reducing the power target repeats the shaping table at a different Vcc reference point.

FIG. 5C is one example of a Smith chart of collector impedance versus control voltage for a load modulated power amplifier. In this example, a dynamic modulation load trajectory is depicted for a change over a voltage range of the envelope control voltage between a first voltage level associated with peak power to a second voltage level associated with MPRO average power.

FIG. 5D is one example of signal, power supply, and load characteristics versus time for a load modulated power amplifier.

In FIG. 5D, results are shown for a transient simulation in which RF signal transmission changes from full transmitted power to reduced transmitted power. At full transmitted power, APT results in the power amplifier supply voltage (Vcc) having a first voltage level (for example, Vcc=5V) while at reduced transmitted power Vcc has a second voltage level (for example, Vcc=3.3V) that is less than the first voltage level. Thus, Vcc follows average signal power in accordance with APT.

As shown in FIG. 5D, as the RF signal changes, the RF load follows the instantaneous power of the RF signal. Additionally, the RF load has a minimum load value and a maximum load value that are based on the Vcc voltage level associated with APT.

In certain embodiments, Vcc is scaled with average power while the shaping table remains constant for two or more power ranges. Additionally, the envelope control voltage (Venv) is offset for a target average power (Pavg). Implementing the calibration in this manner decouples average power from instantaneous power tracking, which provide simplified calibration control that can be stored with a smaller amount of storage space.

In certain implementations, the voltage swing of the shaped envelope signal (Venv) does not change as the voltage level of Vcc changes. For example, the shaped envelope signal (Venv) can operate with a certain peak-to-peak voltage swing (for instance, 250 mV peak to peak) for each value of Vcc. Such constant peak-to-peak voltage swing can be achieved by replicating envelope shaping data that is used for each Vcc but shifted in each power range.

The load control range of the shaped envelope signal (Venv) can be implemented to be substantially constant for two or more power ranges. For example, in the illustrated embodiment, the load control range is about 6 dB for both the first power range (associated with Vcc=5V) and the second power range (associated with Vcc=3.3V).

FIG. 5E is one example of a graph of gain versus output power for a load modulated power amplifier. The graph depicts results for a static Vcc and a power sweep for multiple Venv levels.

The graph can be used to extract an envelope shaping table for Isogain or another desired calibration metric.

Such graphs can be generated for different values of Vcc. In certain implementations, a full power range of the load modulated power amplifier is partitioned in a plurality of power ranges each associated with a corresponding Vcc level.

Although a separate or unique calibration can be performed for each Vcc level, in some embodiments herein, to reduce complexity and storage space for calibration, the same envelope shaping data is replicated for each Vcc but shifted in each power range.

FIG. 5F is one example of a graph of power added efficiency (PAE) versus output power for a load modulated power amplifier. The graph includes results for a static Vcc and a power sweep for multiple Venv levels.

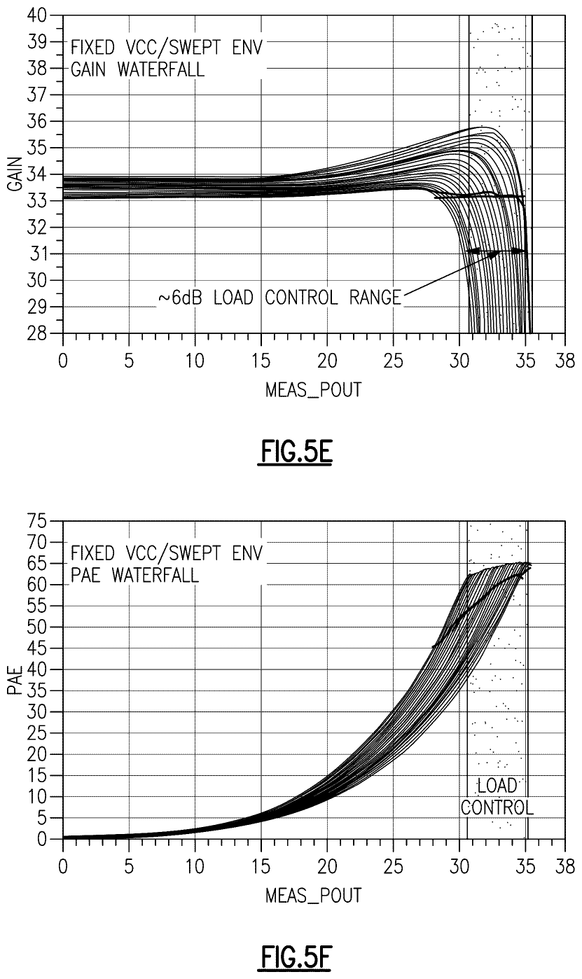

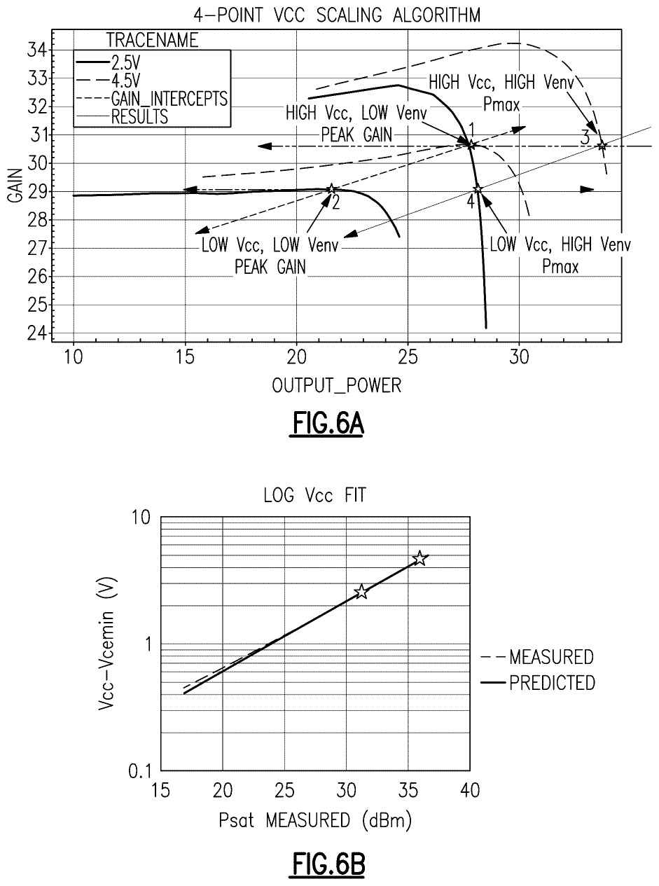

FIG. 6A is one example a graph of a 4-point power supply voltage (Vcc) scaling algorithm according to one embodiment. The scaling algorithm can be used to determine shift versus voltage.

The power supply voltage scales with target peak power to improve efficiency. Thus, the Vcc level can be a function of a required saturated output power (Psat), which is a function of average target power and waveform PAPR or crest factor.

In certain implementations, Vcc calibration (for example, calibration of the Vcc shaping table 205) is performed by a two-point measurement of Psat near max Vcc and min Vcc with the shaped envelope signal (Venv) set at maximum.

In certain implementations, gain calibration (for example, calibration of the gain shaping table 206) is performed by a two-point measurement of gain near max Vcc and min Vcc with the shaped envelope signal (Venv) set at minimum.

The points associate with Vcc and gain calibration are graphically shown as points 1, 2, 3 and 4 on the graph of FIG. 6A.

FIG. 6B is one example of power amplifier supply voltage versus saturated output power after a 2-point calibration for target power and waveform crest factor. As shown in FIG. 6B, measured and predicted values for Vcc closely track one another.

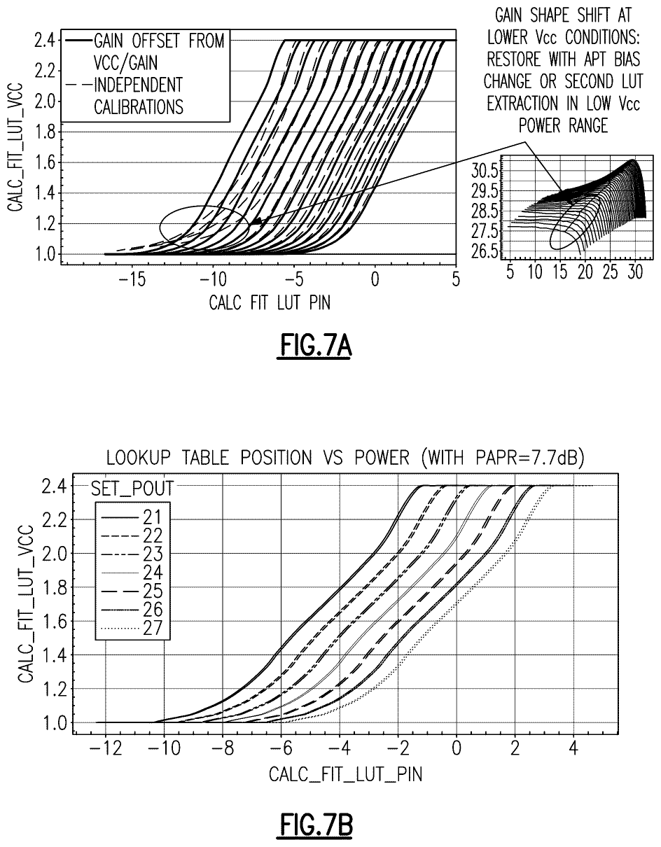

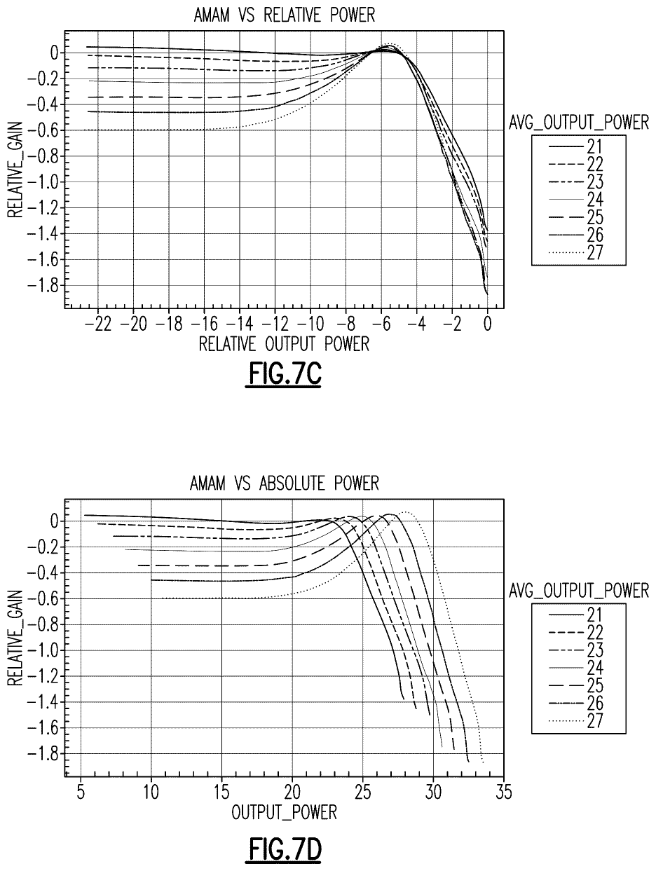

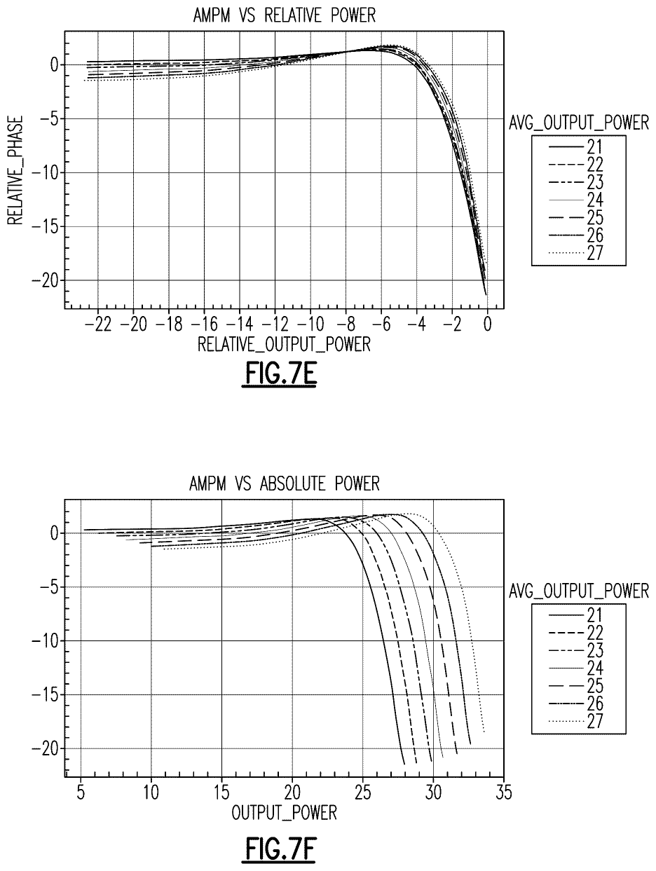

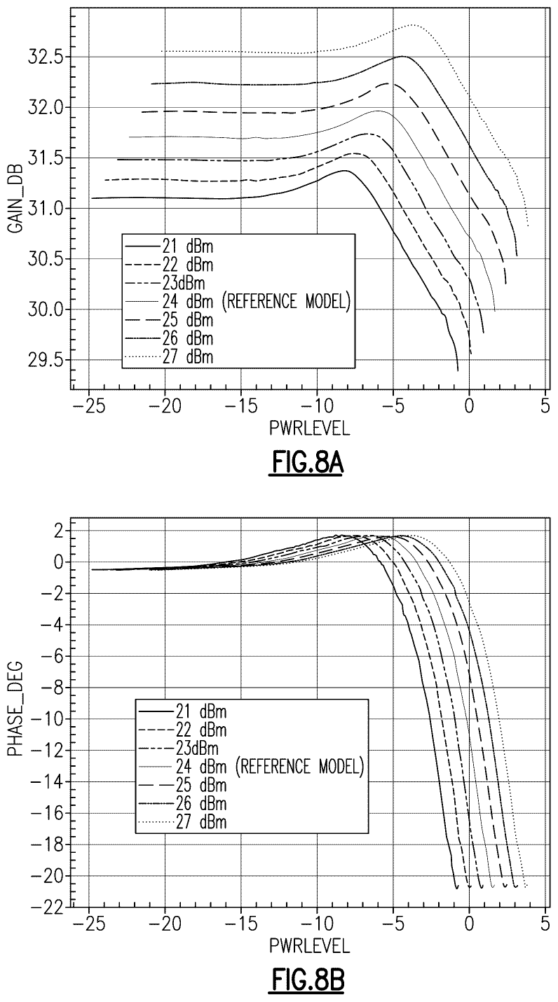

FIG. 7A is one example of a graph of envelope shaping table response versus power range.

A first group of plots (represented by solid lines) for a single extraction that is shifted based on power range are shown alongside a second group of plots (represented by dashed lines) for independent calibrations for each power range and corresponding Vcc. For example, the first group of plots correspond to an example of using replicating envelope shaping data for each Vcc but shifted for each power range.

As shown by FIG. 7A, using replicated envelope shaping data provides good performance over about a 10 dB window. For low Vcc power range an APT bias change can be made and/or unique envelope shaping data can be used to provide better correlation.

FIG. 7B is another example of a graph of envelope shaping table response versus power range. The graph shows that common envelope shaping can be used and shifted with target power (offset by power amplifier gain shift).

With reference to FIGS. 7C to 7F, simulation results for amplitude distortion and phase distortion are shown for a load modulated power amplifier system that uses common envelope shaping that is shifted with target power.

FIG. 7C is one example of a graph of amplitude distortion versus relative output power.

FIG. 7D is one example of a graph of amplitude distortion versus absolute output power.

FIG. 7E is one example of a graph of phase distortion versus relative output power.

FIG. 7F is one example of a graph of phase distortion versus absolute output power.

With reference to FIGS. 8A and 8B, in certain embodiments herein a load modulated power amplifier includes a modulator that provides DPD using a common DPD model that shifts with average power. Thus, a replicated or copied DPD model can be used that is shifted for each power range.

FIG. 8A is one example of a graph of gain versus power level using DPD scaling for a load modulated power amplifier. As shown in FIG. 8A, power and gain scale with Vcc scaling slopes.

FIG. 8B is one example of a graph of phase versus power level using DPD scaling for a load modulated power amplifier. As shown in FIG. 8B, phase and gain scale with Vcc scaling slopes.

### Example Embodiments for Envelope Shaping with Smoothing

A load modulated power amplifier can have an envelope shaping table that is calibrated for Isogain. Envelope shaping tables calibrated for Isogain can provide a response characteristic that achieves a constant gain of the power amplifier.

Although calibrating the load modulated power amplifier in this manner can provide low gain distortion (AM/AM), the inventors herein have recognized that an Isogain calibration can result in phase distortion (AM/PM). For example, load modulation can change a capacitance in the power amplifier's load over time, which can de-tune the quality-factor (Q-factor) of the power amplifier's load and cause a corresponding phase distortion error.

To compensate for this phase distortion, in certain embodiments the envelope shaping table is smoothed at least at a lower end of the power range relative to an envelope shaping table calibrated for Isogain. By providing smoothing in this manner, spectral regrowth can be reduced. In certain implementations, the envelope shaping table is also smoothed for an upper end of the power range, which aids in reducing receive noise that could otherwise impact a nearby receiver.

Thus, in some embodiments herein, calibration of envelope shaping is performed to achieve a desired phase performance (for example, AM/PM shape). In certain implementations, a degree of smoothing is performed to achieve less than −120 dBm of phase distortion while achieving less than −130 dBm of amplitude distortion.

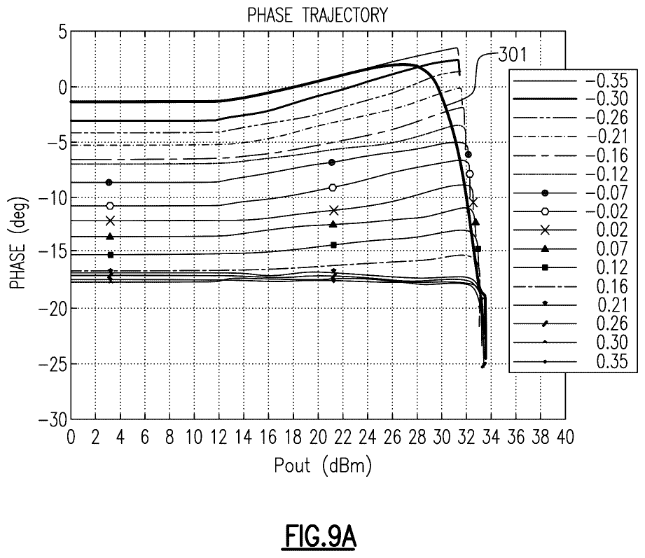

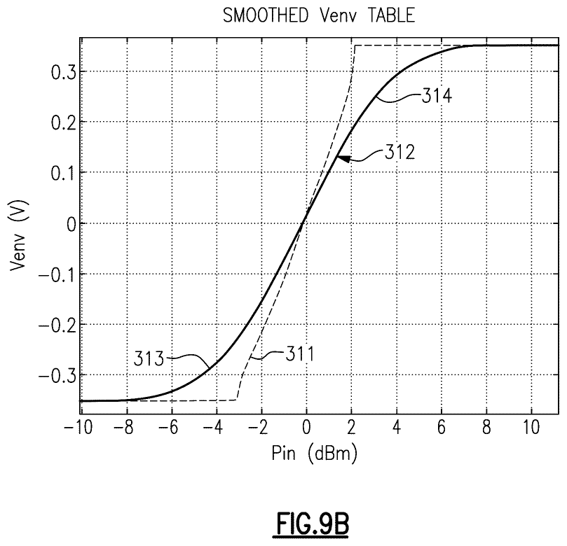

FIG. 9A is one example of a graph of phase versus output power for a load modulated power amplifier. The graph depicts phase waterfall characteristics or phase trajectories present in the phase versus output power plots. The graph includes a phase trajectory 301 when an Isogain calibration is used. The phase trajectory 301 is associated with phase distortion and spurious emissions from the power amplifier.

FIG. 9B is one example of a graph of shaped envelope voltage versus input power with and without smoothing for a load modulated power amplifier. The graph includes a first response 311 of shaped envelope voltage versus input power without smoothing and a second response 312 of shaped envelope voltage versus input power with smoothing.

In the illustrated example, smoothing is performed for both a lower end 313 of the power range as well as for an upper end 314 of the power range. Providing shaping for the lower end 313 of the power range improves phase distortion and reduces spectral regrowth, while providing shaping for the upper end 314 of the power range improves receive noise.

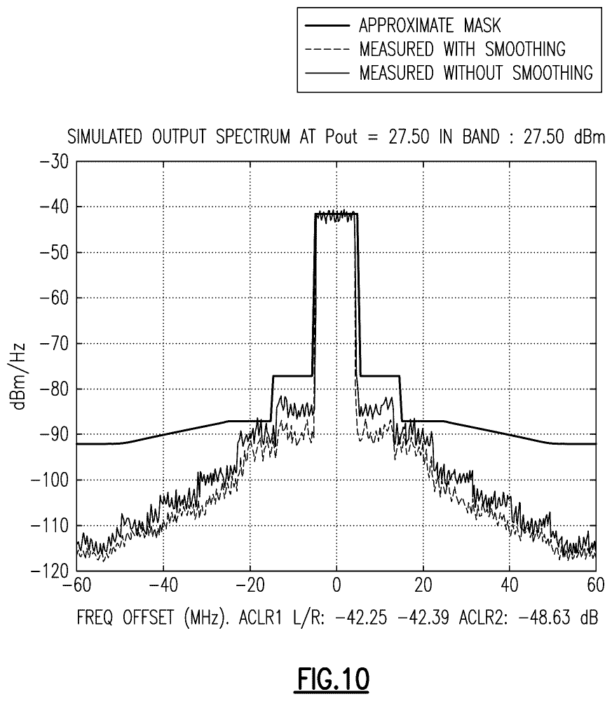

FIG. 10 is one example of a graph of output spectrum versus frequency offset. Measured results with and without smoothing are shown alongside an approximate power mask. As shown in FIG. 10, using an envelope shaping table with smoothing improves the output spectrum by reducing adjacent channel leakage ratio and spectral regrowth.

### Example Embodiments of Mobile Device and Packaged Module

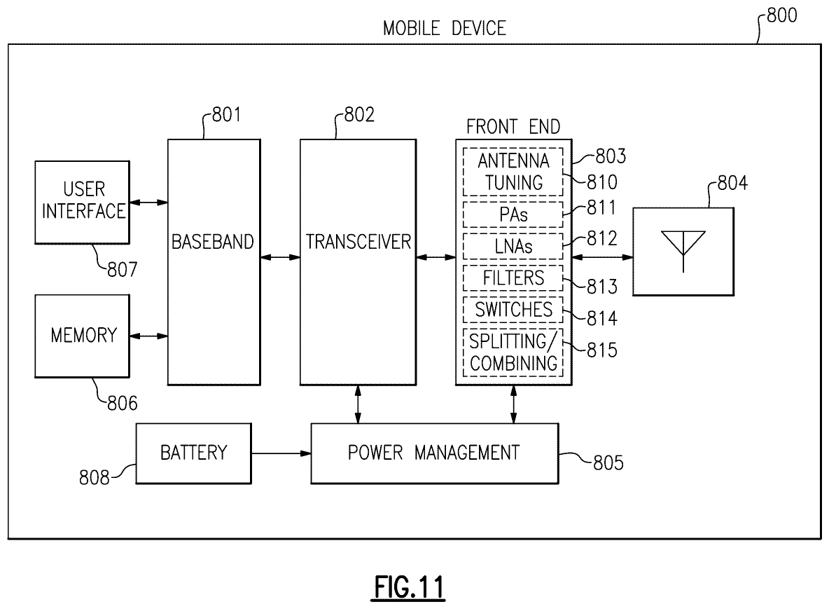

FIG. 11 is a schematic diagram of one embodiment of a mobile device 800. The mobile device 800 includes a baseband system 801, a transceiver 802, a front end system 803, antennas 804, a power management system 805, a memory 806, a user interface 807, and a battery 808.

The mobile device 800 can be used communicate using a wide variety of communications technologies, including, but not limited to, 2G, 3G, 4G (including LTE, LTE-Advanced, and LTE-Advanced Pro), 5G NR, WLAN (for instance, WiFi), WPAN (for instance, Bluetooth and ZigBee), WMAN (for instance, WiMax), and/or GPS technologies.

The transceiver 802 generates RF signals for transmission and processes incoming RF signals received from the antennas 804. It will be understood that various functionalities associated with the transmission and receiving of RF signals can be achieved by one or more components that are collectively represented in FIG. 11 as the transceiver 802. In one example, separate components (for instance, separate circuits or dies) can be provided for handling certain types of RF signals.

The front end system 803 aids in conditioning signals transmitted to and/or received from the antennas 804. In the illustrated embodiment, the front end system 803 includes antenna tuning circuitry 810, power amplifiers (PAS) 811, low noise amplifiers (LNAs) 812, filters 813, switches 814, and signal splitting/combining circuitry 815. However, other implementations are possible.

For example, the front end system 803 can provide a number of functionalities, including, but not limited to, amplifying signals for transmission, amplifying received signals, filtering signals, switching between different bands, switching between different power modes, switching between transmission and receiving modes, duplexing of signals, multiplexing of signals (for instance, diplexing or triplexing), or some combination thereof.

At least one of the power amplifiers 811 is implemented as a load modulated power amplifier in accordance with the teachings herein. Although the mobile device 800 illustrates one embodiment of a communication system that can be implemented with one or more load modulated power amplifiers, the teachings herein are applicable to a wide range of systems. Accordingly, other implementations are possible.

In certain implementations, the mobile device 800 supports carrier aggregation, thereby providing flexibility to increase peak data rates. Carrier aggregation can be used for both Frequency Division Duplexing (FDD) and Time Division Duplexing (TDD), and may be used to aggregate a plurality of carriers or channels. Carrier aggregation includes contiguous aggregation, in which contiguous carriers within the same operating frequency band are aggregated. Carrier aggregation can also be non-contiguous, and can include carriers separated in frequency within a common band or in different bands.

The antennas 804 can include antennas used for a wide variety of types of communications. For example, the antennas 804 can include antennas for transmitting and/or receiving signals associated with a wide variety of frequencies and communications standards.

In certain implementations, the antennas 804 support MIMO communications and/or switched diversity communications. For example, MIMO communications use multiple antennas for communicating multiple data streams over a single radio frequency channel. MIMO communications benefit from higher signal to noise ratio, improved coding, and/or reduced signal interference due to spatial multiplexing differences of the radio environment. Switched diversity refers to communications in which a particular antenna is selected for operation at a particular time. For example, a switch can be used to select a particular antenna from a group of antennas based on a variety of factors, such as an observed bit error rate and/or a signal strength indicator.

The mobile device 800 can operate with beamforming in certain implementations. For example, the front end system 803 can include amplifiers having controllable gain and phase shifters having controllable phase to provide beam formation and directivity for transmission and/or reception of signals using the antennas 804. For example, in the context of signal transmission, the amplitude and phases of the transmit signals provided to the antennas 804 are controlled such that radiated signals from the antennas 804 combine using constructive and destructive interference to generate an aggregate transmit signal exhibiting beam-like qualities with more signal strength propagating in a given direction. In the context of signal reception, the amplitude and phases are controlled such that more signal energy is received when the signal is arriving to the antennas 804 from a particular direction. In certain implementations, the antennas 804 include one or more arrays of antenna elements to enhance beamforming.

The baseband system 801 is coupled to the user interface 807 to facilitate processing of various user input and output (I/O), such as voice and data. The baseband system 801 provides the transceiver 802 with digital representations of transmit signals, which the transceiver 802 processes to generate RF signals for transmission. The baseband system 801 also processes digital representations of received signals provided by the transceiver 802. As shown in FIG. 11, the baseband system 801 is coupled to the memory 806 of facilitate operation of the mobile device 800.

The memory 806 can be used for a wide variety of purposes, such as storing data and/or instructions to facilitate the operation of the mobile device 800 and/or to provide storage of user information.

The power management system 805 provides a number of power management functions of the mobile device 800. In certain implementations, the power management system 805 includes a PA supply control circuit that controls the supply voltages of the power amplifiers 811. For example, the power management system 805 can be configured to change the supply voltage(s) provided to one or more of the power amplifiers 811 to improve efficiency, such as power added efficiency (PAE).

As shown in FIG. 11, the power management system 805 receives a battery voltage from the battery 808. The battery 808 can be any suitable battery for use in the mobile device 800, including, for example, a lithium-ion battery.

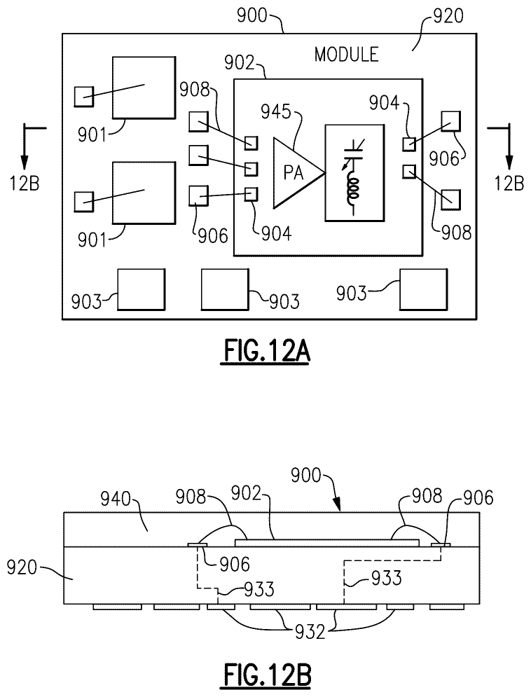

FIG. 12A is a schematic diagram of one embodiment of a packaged module 900. FIG. 12B is a schematic diagram of a cross-section of the packaged module 900 of FIG. 12A taken along the lines 12B-12B.

The packaged module 900 includes radio frequency components 901, a semiconductor die 902, surface mount devices 903, wirebonds 908, a package substrate 920, and an encapsulation structure 940. The package substrate 920 includes pads 906 formed from conductors disposed therein. Additionally, the semiconductor die 902 includes pins or pads 904, and the wirebonds 908 have been used to connect the pads 904 of the die 902 to the pads 906 of the package substrate 920.

The semiconductor die 902 includes a load modulated power amplifier 945, which can be implemented in accordance with any of the embodiments herein.

The packaging substrate 920 can be configured to receive a plurality of components such as radio frequency components 901, the semiconductor die 902 and the surface mount devices 903, which can include, for example, surface mount capacitors and/or inductors. In one implementation, the radio frequency components 901 include integrated passive devices (IPDs).

As shown in FIG. 12B, the packaged module 900 is shown to include a plurality of contact pads 932 disposed on the side of the packaged module 900 opposite the side used to mount the semiconductor die 902. Configuring the packaged module 900 in this manner can aid in connecting the packaged module 900 to a circuit board, such as a phone board of a mobile device. The example contact pads 932 can be configured to provide radio frequency signals, bias signals, and/or power (for example, a power supply voltage and ground) to the semiconductor die 902 and/or other components. As shown in FIG. 12B, the electrical connections between the contact pads 932 and the semiconductor die 902 can be facilitated by connections 933 through the package substrate 920. The connections 933 can represent electrical paths formed through the package substrate 920, such as connections associated with vias and conductors of a multilayer laminated package substrate.

In some embodiments, the packaged module 900 can also include one or more packaging structures to, for example, provide protection and/or facilitate handling. Such a packaging structure can include overmold or encapsulation structure 940 formed over the packaging substrate 920 and the components and die(s) disposed thereon.

It will be understood that although the packaged module 900 is described in the context of electrical connections based on wirebonds, one or more features of the present disclosure can also be implemented in other packaging configurations, including, for example, flip-chip configurations.

### Conclusion

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “may,” “could,” “might,” “can,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings of the invention provided herein can be applied to other systems, not necessarily the system described above. The elements and acts of the various embodiments described above can be combined to provide further embodiments.

While certain embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

What is claimed is:

1. A load modulated power amplifier system comprising:
a power amplifier configured to receive a radio frequency signal at an input and to provide an amplified radio frequency signal at an output, the power amplifier powered by a power amplifier supply voltage;
a controllable load impedance coupled to the output of the power amplifier and having an impedance controlled by a shaped envelope signal;
a power management circuit configured to control a voltage level of the power amplifier supply voltage based on a power target signal; and
an envelope shaping table configured to generate the shaped envelope signal based on a signal power of the radio frequency signal, the envelope shaping table providing a first response characteristic for a first power range and a second response characteristic for a second power range, the second response characteristic corresponding to a shifted copy of the first response characteristic.

2. The load modulated power amplifier system of claim 1 wherein the power management circuit sets the power amplifier supply voltage to a first voltage level for the first power range and to a second voltage level for the second power range.

3. The load modulated power amplifier system of claim 1 wherein the power management circuit provides average power tracking based on the power target signal.

4. The load modulated power amplifier system of claim 1 further comprising a supply voltage shaping table configured to generate a shaped power supply reference signal for the power management circuit based on the power target signal.

5. The load modulated power amplifier system of claim 4 further comprising a gain shaping table configured to generate a shaped gain control signal for scaling the radio frequency signal based on the power target signal.

6. The load modulated power amplifier system of claim 5 further comprising a modulator configured to generate the radio frequency signal based on digital signal data, the modulator receiving the shaped gain control signal, the shaped envelope table receiving the digital signal data to determine the signal power.

7. The load modulated power amplifier system of claim 5 wherein the supply voltage shaping table and the gain shaping table are calibrated by a four-point calibration.

8. The load modulated power amplifier system of claim 7 wherein the four-point calibration includes a first calibration point of a gain of the power amplifier for a high setting of the power amplifier supply voltage and a low setting of the shaped envelope signal, a second calibration point for the gain for a low setting of the power amplifier supply voltage and the low setting of the shaped envelope signal, a third calibration point for an output power of the power amplifier for the high setting of the power amplifier supply voltage and the high setting of the shaped envelope signal, and a fourth calibration point for the output power for the low setting of the power amplifier supply voltage and the high setting of the shaped envelope signal.

9. The load modulated power amplifier system of claim 1 wherein the envelope shaping table provides a third response characteristic for a third power range, the third response characteristic corresponding to a shifted copy of the second response characteristic.

10. The load modulated power amplifier system of claim 1 further comprising a modulator configured to generate the radio frequency signal based on digital signal data.

11. The load modulated power amplifier system of claim 10 wherein the modulator provides digital pre-distortion to the radio frequency signal, the modulator having a first digital pre-distortion model for the first power range and a second digital pre-distortion model for the second power range, the second digital pre-distortion model corresponding to a shifted copy of the first digital pre-distortion model.

12. The load modulated power amplifier system of claim 10 wherein the shaped envelope table receives the digital signal data to determine the signal power.

13. A mobile device comprising:
a front end system including a power amplifier configured to receive a radio frequency signal at an input and to provide an amplified radio frequency signal at an output, and a controllable load impedance coupled to the output of the power amplifier and having an impedance controlled by a shaped envelope signal;
a power management circuit configured to control a voltage level of a power amplifier supply voltage of the power amplifier based on a power target signal; and
a transceiver configured to generate the radio frequency signal, the transceiver including an envelope shaping table configured to generate the shaped envelope signal based on a signal power of the radio frequency signal, the envelope shaping table providing a first response characteristic for a first power range and a second response characteristic for a second power range, the second response characteristic corresponding to a shifted copy of the first response characteristic.

14. The mobile device of claim 13 wherein the transceiver further includes a supply voltage shaping table configured to generate a shaped power supply reference signal for the power management circuit based on the power target signal.

15. The mobile device of claim 14 wherein the transceiver further includes a gain shaping table configured to generate a shaped gain control signal for scaling the radio frequency signal based on the power target signal.

16. The mobile device of claim 15 wherein the transceiver further includes a modulator configured to generate the radio frequency signal based on digital signal data, the modulator receiving the shaped gain control signal, the shaped envelope table receiving the digital signal data to determine the signal power.

17. The mobile device of claim 15 wherein the supply voltage shaping table and the gain shaping table are calibrated by a four-point calibration.

18. The mobile device of claim 17 wherein the four-point calibration includes a first calibration point of a gain of the power amplifier for a high setting of the power amplifier supply voltage and a low setting of the shaped envelope signal, a second calibration point for the gain for a low setting of the power amplifier supply voltage and the low setting of the shaped envelope signal, a third calibration point for an output power of the power amplifier for the high setting of the power amplifier supply voltage and the high setting of the shaped envelope signal, and a fourth calibration point for the output power for the low setting of the power amplifier supply voltage and the high setting of the shaped envelope signal.

19. A method of power amplification in a mobile device, the method comprising:
receiving a radio frequency signal at an input to a power amplifier and providing an amplified radio frequency signal at an output of the power amplifier;
controlling a voltage level of a power amplifier supply voltage of the power amplifier based on a power target signal using a power management circuit;
controlling an impedance of a controllable load impedance coupled to the output of the power amplifier using a shaped envelope signal; and
generating the shaped envelope signal based on a signal power of the radio frequency signal using an envelope shaping table that provides a first response characteristic for a first power range and a second response characteristic for a second power range, the second response characteristic corresponding to a shifted copy of the first response characteristic.

20. The method of claim 19 further comprising setting the power amplifier supply voltage to a first voltage level for the first power range and to a second voltage level for the second power range using the power management circuit.
